(19) United States
(12) Patent Application Publication
(10) Pub. No.: US 2018/0358494 A1
(43) Pub. Date: Dec. 13, 2018

(54) PHOTOVOLTAIC MODULE COMPRISING A POLYMER LAYER PROVIDED WITH RECESSES FORMING EXPANSION JOINTS

(71) Applicants: COMMISSARIAT A L'ENERGIE ATOMIQUE ET AUX ENERGIES ALTERNATIVES, Paris (FR); ARKEMA FRANCE, Colombes (FR)

(72) Inventors: Eric PILAT, Brison-Saint -Innocent (FR); Manuel HIDALGO, Brignais (FR); Dominique THIL, Cessieu (FR); Marion VITE, Chambery (FR)

(73) Assignee: COMMISSARIAT A L'ENERGIE ATOMIQUE ET AUX ENERGIES ALTERNATIVES, Paris (FR)

(21) Appl. No.: 15/539,469

(22) PCT Filed: Dec. 18, 2015
(86) PCT No.: PCT/EP2015/080432

§ 371 Date: Jun. 23, 2017

(30) Foreign Application Priority Data
Dec. 26, 2014 (FR) 1463351

(51) Int. Cl. H01L 31/048; H01L 31/05

(52) U.S. Cl. CPC H01L 31/0481; H01L 31/0504

(57) ABSTRACT

The invention is directed to a photovoltaic module containing at least one first transparent layer forming the front face of the module, a plurality of photovoltaic cells, an encapsulating assembly encapsulating the plurality of photovoltaic cells, a second layer forming the rear face of the module, characterized in that at least one of the first and second layers is composed of a polymer material, in which recesses are formed that constitute expansion joints, produced as a one-piece component, and in that the recesses are at least partially occupied by a “soft” joining material having a Young's modulus less than that of the polymer material of the at least one of the first and second layers and a thickness less than or equal to that of the at least one of the first and second layers. The recesses are at least partially through-recesses.

### TECHNICAL DOMAIN

This invention relates to the domain of photovoltaic modules that comprise a set of photovoltaic cells electrically connected to each other, and particularly “crystalline” photovoltaic cells, in other words based on silicon crystals or silicon polycrystals.

The invention can be used for many applications, since it is concerned particularly by applications that require the use of photovoltaic modules that have front and/or back faces made from thick polymer materials with a high coefficient of expansion, particularly with a thickness of 0.5 mm or more. It can thus be applied particularly for buildings such as homes or industrial premises, for example for the construction of their roofs, for the design of urban furniture, for example for public lighting, road signs or recharging electric cars, or for integration in traffic areas, for pedestrians and/or vehicles, such as roads or tracks, cycle tracks, industrial platforms, squares, pavements, and can even be used for nomad applications particularly for integration on cars, buses or boats, and others.

The invention thus discloses a photovoltaic module comprising a polymer layer provided with slots forming expansion joints, and a method of making such a photovoltaic module.

### STATE OF PRIOR ART

A photovoltaic module is an assembly of photovoltaic cells arranged side by side between a first transparent layer forming a front face of the photovoltaic module and a second layer forming a back face of the photovoltaic module.

The first layer forming the front face of the photovoltaic module is advantageously transparent so that the photovoltaic cells can receive a light flux. It is traditionally made from a single glass pane typically between 2 and 4 mm thick, and particularly of the order of 3 mm thick.

The second layer forming the back face of the photovoltaic module can be made based on glass, metal or plastic, among other materials. It is often composed of a polymer structure based on an electrically insulating polymer, for example of the polyethylene terephthalate (PET) or polyamide (PA) type, that can be protected by one or more layers based on fluorinated polymers, such as polyvinyl fluoride (PVF) or polyvinylidene fluoride (PVDF), and with a thickness of the order of 300 μm.

The photovoltaic cells can be electrically connected to each other in series by front and back electrical contact elements called connecting conductors, formed for example from copper strips in contact with the front face (face facing the front face of the photovoltaic module that will receive a light flux) and the back face (face facing the back face of the photovoltaic module) of each photovoltaic cell.

Furthermore, the photovoltaic cells located between the first and second layers forming the front and back faces respectively of the photovoltaic module, can be encapsulated. Conventionally, the chosen encapsulating agent is an elastomer type polymer (or rubber), and for example can consist of using two poly(ethylene vinyl acetate) (EVA) layers (or films) between which the photovoltaic cells and cell connection conductors are located. Each encapsulating layer can be at least 0.3 mm thick and have a Young's modulus typically between 2 and 400 MPa at ambient temperature.

Thus, a conventional example of a photovoltaic module 1 comprising crystalline photovoltaic cells 4 is shown partially and diagrammatically on FIG. 1 and in an exploded view on FIG. 2.

As mentioned above, the photovoltaic module 1 comprises a front face 2, usually made from transparent toughened glass between 2 and 4 mm thick, and a back face 5, for example composed of an opaque or transparent single-layer or multiple-layer sheet, with a Young's modulus of more than 400 MPa at ambient temperature.

Photovoltaic cells 4 are located between the front face 2 and the back face 5 of the photovoltaic module 1 and are electrically connected together in series by connecting conductors 6 embedded between two layers, the front layer 3a and the back layer 3b of the encapsulation material both of which form an encapsulating assembly 3.

Normally, the method of manufacturing the photovoltaic module 1 comprises a step called lamination of the different layers described above, at a temperature greater than or equal to 100° C., or even 140° C., or even better 150° C., and less than or equal to 170° C., typically between 145 and 160° C., and during a period of at least 8 minutes, or even 15 minutes.

During this lamination step, the layers of encapsulation material 3a and 3b melt and surround the photovoltaic cells 4, and at the same time adhesion is developed at all interfaces between layers, namely between the front face 2 and the front layer of the encapsulation material 3a, the layer of encapsulation material 3a and the front faces 4a of the photovoltaic cells 4, the back faces 4b of the photovoltaic cells 4 and the back layer of the encapsulation material 3b, and the back layer of the encapsulation material 3b and the back face 5 of the photovoltaic material 1. Moreover, the lamination step is also a step during which some “cross-linkable” encapsulants have a so-called cross-linking reaction that fixes their mechanical properties in the extreme upper range of the working temperatures.

During this rolling operation (also referred to as lamination in this description), the two layers of encapsulation material 3a and 3b are melted so that after the lamination operation, they form a single encapsulating assembly layer 3 in which the photovoltaic cells 4 are embedded.

Furthermore, during the lamination step, the laminate (structure that should form the photovoltaic module as shown on FIGS. 1 and 2) is placed inside heating equipment comprising two chambers (upper and lower). It is placed firstly in the lower chamber, in contact with a heating plate, and remains separated from the upper chamber by a flexible membrane such that the rolling operation comprises at least two successive stages: the first during which a vacuum is formed in the two chambers so as to degas the laminate and to bring it to thermal equilibrium, the second during which pressure is returned to about atmospheric pressure in the upper chamber such that the laminate is hot compressed by the pressure difference between the two chambers.

Nevertheless, there are several disadvantages with such a lamination step to make the photovoltaic module, particularly when the front face et/or the back face of the photovoltaic module are made of a polymer material, which can be the case if it is required to reduce the weight or for more flexibility than is possible with glass.

Lamination has the major disadvantages of applying thermal loads on the structure that will form the photovoltaic module during manufacturing, and will cause different responses in terms of expansion stresses in the different layers, particularly between the polymer front face and/or back face and the other layers.

These disadvantages persist every time that the photovoltaic module is subjected to large temperature differences other than those that occur during the lamination step, therefore after manufacturing of the photovoltaic module, particularly during normalised tests under hardened conditions, supposed to guarantee good resistance of the photovoltaic module throughout its life. For example, there is the thermal cycling test during which the photovoltaic module is subjected to at least 200 relatively fast cycles, typically between 4 and 6 per day, with temperature changes between −40° C. and 85° C.

Furthermore, as indicated above, these disadvantages are particularly severe when the front face and/or the back face of the photovoltaic module, normally made from thick and therefore very stiff glass, is/are replaced by a lighter weight polymer type material, less brittle than glass, to make significantly thinner but consequently significantly less stiff front and back faces, for example such as polycarbonate (PC) or polymethyl methacrylate (PMMA). In this case, stresses induced by differential expansion of the different layers of the photovoltaic module can be such that delamination within the different interfaces of the module, or even breakages of photovoltaic cells, movements of connecting conductors, breakages of the front and/or back faces of the module and/or warping/deflection of the module, can occur.

A first solution to solve these problems could then be to design perfectly symmetrical structures for photovoltaic modules that make it necessary to use the same material for the front face and the back face of the module, which is not always desirable or achievable. Furthermore, having materials with the same coefficient of expansion on the front and back faces of the photovoltaic module does not constitute a remedy when a temperature differential is created in situations in which the front are back faces and exposed to different temperatures.

A second solution would be to use a very thick encapsulating assembly with a low Young's modulus. In this way, it would be the encapsulating assembly that would deform, and by deforming would avoid the generation of excessive stresses. However, this solution is not fully satisfactory for the following reasons: by increasing the thickness of the encapsulating assembly, it becomes heavier and less flexible, and especially its manufacturing cost is too high; also, subject to repeated cycles, fatigue in the encapsulating assembly develops relatively quickly and there is a high risk of creep; finally, an excessively thick layer of encapsulant will also reduce the flux of photons that can be captured by photovoltaic cells.

Furthermore, solutions regarding the problem of thermal expansion in photovoltaic modules have also disclosed in patent literature.

Thus for example, international application WO 2013/160375 A2 describes an adaptation of the characteristics of the materials of a photovoltaic module to attenuate optical losses and mechanical constraints. In particular, it discloses the use of an encapsulant with a low Young's modulus capable of accommodating differential expansions by deformation.

Furthermore, international applications WO 2009/109180 A2 and WO 2012/009681 A2 disclose the addition of additives with a low coefficient of thermal expansion (CTE) in the material of the front face, the back face or the encapsulant of the photovoltaic module, so as to reduce the global coefficient of thermal expansion of the material, and also to improve the thermal conductivity of the material.

Nevertheless, these solutions according to prior art seem to be insufficient, because the Young's modulus of encapsulants currently used is already quite low, and they are also expensive or too complex to implement (additives).

### PRESENTATION OF THE INVENTION

There is a need to design an alternative solution to the photovoltaic module designed to reduce the disadvantages related to the thermal expansion phenomenon of its components when subjected to temperature variations, and particularly when these components made from materials with very different natures and very different thermomechanical properties have a high coefficient of thermal expansion.

The purpose of the invention is to at least partially remedy the needs mentioned above and the disadvantages in embodiments according to prior art.

Another purpose of one aspect of the invention is a photovoltaic module comprising at least:
a first transparent layer forming the front face of the photovoltaic module that will receive a light flux,
a plurality of photovoltaic cells arranged side by side and electrically connected together,
an assembly encapsulating the plurality of photovoltaic cells,
a second layer forming the back face of the photovoltaic module, the encapsulating assembly and the plurality of photovoltaic cells being located between the first and the second layers,
   characterised in that at least the first or the second layer is composed of at least one polymer material, in which slots are formed making up expansion joints, said at least first or second layer provided with slots being one integral piece, and in that the slots are at least partially occupied by a “soft” jointing material with a Young's modulus at ambient temperature being less than the Young's modulus at ambient temperature of the polymer material of said at least first or second layer and with the same thickness as the polymer material of said at least first or second layer, or thinner.

The term “transparent” means that the material of the first layer forming the front face of the photovoltaic module is at least partially transparent to visible light, allowing at least about 80% of this light to pass through.

Furthermore, the term “encapsulating” or “encapsulated” means that the plurality of photovoltaic cells is located inside a volume, for example hermetically sealed against liquids, at least partly formed by at least two layers of encapsulating material, connected to each other by rolling to form the encapsulating assembly.

Initially, in other words before any rolling activity, the encapsulating assembly consists of at least two layers of encapsulation material, called core layers, between which the plurality of photovoltaic cells is located. However, during the layer rolling operation, the layers of encapsulation material melt so that, after the rolling activity, only a single solidified layer (or assembly) is formed, in which the photovoltaic cells are embedded.

As indicated above, the encapsulating assembly can be formed from at least two layers of encapsulation material with identical or different thicknesses, comprising an elastomer type polymer (or rubber). For example, each core layer may consist of a poly(ethylene vinyl acetate) (EVA) layer (or film). Each core layer can be at least 0.3 mm thick and have a Young's modulus typically between 2 and 400 MPa at ambient temperature.

Furthermore, the expression “ambient temperature” means a temperature of between about 15 and 30° C.

Thus, due to the invention, it can be possible to reduce stresses due to thermal expansion of the layers forming a photovoltaic module when large temperature variations are applied to the module. In particular, the presence of slots forming expansion joints in the front face and/or the back face of the photovoltaic module, in other words in an “external” face of the module, can solve some of the problems mentioned above. The presence of a soft material in the slots of such an external face can create rupture zones in the polymer material on the outside face that would attenuate the disadvantages related to thermal expansion.

The photovoltaic module according to the invention can also comprise one or several of the following characteristics that may be taken in isolation or in any possible technical combination.

The Young's modulus is advantageously measured using the measurement method given in standard ISO 527-1:1993, dated Jun. 15, 1993, superseded in 2012 by ISO standard 527-1:2012.

Preferably, said at least one of the first and second layers corresponds to the first layer of the photovoltaic module, in other words its front face. As a variant, it may also be the second layer of the photovoltaic module, in other words its back face.

The jointing material can have a Young's modulus at ambient temperature of 20 times less, or even 100 times or even 500 times or even 1000 times less than the Young's modulus at ambient temperature of the polymer material of said at least one of the first and second layers.

In particular, the jointing material can have a Young's modulus at ambient temperature of less than or equal to 50 MPa, or even 30 MPa, or even 10 MPa. Furthermore, the polymer material of said at least one of the first and second layers can have a Young's modulus at ambient temperature of between 400 MPa and 10 GPa.

Furthermore, the thickness of the polymer material of said at least one of the first and second layers can be between 0.5 and 10 mm.

Furthermore, the coefficient of thermal expansion (CTE) of the polymer material of said at least one of the first and second layers may be between 30 and 200 ppm/° C. at temperatures close to ambient temperature. Similarly, the coefficient of thermal expansion (CTE) of the jointing material occupying the slots may be between 30 and 500 ppm/° C. at temperatures close to ambient temperature.

Said at least one polymer material of said at least either the first or second layer may be chosen from among poly methyl methacrylate (PMMA), particularly single-phase (non-impact) PMMA or multi-phase (impact) PMMA, particularly nanostructured impact PMMA, or polycarbonate (PC).

Furthermore, the jointing material occupying the slots can be chosen from among a polymer material, particularly identical to the polymer material forming the encapsulating assembly or a gas, possibly ambient air.

Advantageously, the jointing material has a good elastic return, and is flexible and lightweight in comparison with the polymer material of said at least one of the first or second layers, to assure that it can perform its role as an expansion joint in the case of high thermal stresses.

According to one embodiment of the invention, the jointing material is a material, particularly in solid or gas form, that at least partially occupies the slot.

However, it is important to note that in another embodiment of the invention, the jointing material is simply ambient air. In other words, each slot can be occupied by air alone. Furthermore, the expression “jointing material” in the invention corresponds to the effective presence of a material, particularly in solid or gas form, or the presence of ambient air.

Furthermore, each of the first and second layers can be composed of at least one polymer material, in which slots are formed making up expansion joints, each of the first and second layers provided with slots being one integral piece, and the slots being at least partially occupied by a “soft” jointing material with a Young's modulus at ambient temperature being less than the Young's modulus of each of the first and second layers and with a thickness less than or equal to the thickness of each of said first and second layers.

Moreover, the slots are preferably elongated, and in particular may be oblong, along straight lines and/or in the form of the arc of a circle.

The slots advantageously comprise firstly a set of first slots said to be “parallel”, in other words first slots for which their largest dimensions extend along first directions (or orientations) approximately parallel to each other or coincident with each other, and secondly a set of second “perpendicular” slots, in other words second slots for which their largest dimensions extend along second directions (or orientations) approximately perpendicular to the first directions (or orientations) along which the largest dimensions of the first slots extend.

In particular, the first parallel slots may be slots for which their largest dimensions extend along straight lines, all parallel to each other or coincident with each other. The first parallel slots may also be slots for which their largest dimensions extend along curved lines, all parallel to each other or coincident with each other. “Two curved directions parallel to each other” refers to the directions of the locations of the ends of a constant length segment moving orthogonally to its direction. Moreover, for two curved directions parallel to each other, every normal to one is also normal to the other.

Furthermore, the distance between two so-called “adjacent” first parallel slots, in other words two first parallel slots for which their largest dimensions extend along first directions that are practically coincident with each other and for which there are no other first slots between them, or two first parallel slots for which their largest dimensions extend along first approximately parallel directions and for which there are no other first directions along which a first parallel slot extends, is advantageously less than or equal to 200 mm.

If the distance between two adjacent first slots exceeds 200 mm, the stressing effects of differential thermal expansion can be too high.

Furthermore, the distance between two so-called “adjacent” first parallel slots, in other words two first parallel slots for which their largest dimensions extend along first directions that are practically coincident with each other and for which there are no other first slots between them, or two first parallel slots for which their largest dimensions extend along first approximately parallel directions and for which there are no other first directions along which a first parallel slot extends, is advantageously greater than or equal to 40 mm.

If the distance between two adjacent first slots is less than 40 mm, it is no longer possible to provide impact protection and moisture barrier protection functions for said at least one of the first and second layers. Furthermore, the optical quality of said at least one of the first and second layers can be degraded.

Furthermore, the section of the material remaining between a first parallel slot and a second perpendicular slot can be greater than or equal to 2 mm².

If this value is less than 2 mm² for the section of residual material between a first parallel slot and a second perpendicular slot, said at least one of the first and second layers may not be strong enough to be easily handled.

Furthermore, the width of the slots may be 2 mm or more.

If the value of the width of slots is less than 2 mm, the formation of slots, for example by making a casting mould or by machining, may become too expensive.

The width of the slots may also be less than or equal to 3 mm or more.

If the width of slots is more than 3 mm, impact protection and moisture barrier protection functions and the optical quality of said at least one of the first and second layers can be degraded.

Slots may also be at least partly, and particularly entirely, blind.

“Blind slot” means that there is a substantial thickness of material remaining in said at least one of the first and second layers or below the slot. In other words, the part of the contour along the largest dimension of a blind slot is delimited at least on one side by a residual thickness of material from at least one of the first and second layers. The term blind slot is in general use.

Slots may be closed off on the external surface of the photovoltaic module. Slots may also be closed off on the internal surface of the photovoltaic module, particularly on the encapsulating assembly.

The residual thickness of material from said at least one of the first and second layers at the blind slots can be less than or equal to 20% of the thickness of the polymer material in said at least one of the first and second layers, particularly less than or equal to 0.1 mm.

The effectiveness of expansion joints formed by the slots is significantly degraded if the residual thickness of material in said at least one of the first and second layers in blind slots exceeds approximately this value.

Furthermore, slots may also be at least partly, and particularly entirely, open through the thickness.

“Through slot” means that there is no thickness of material remaining in said at least one of the first and second layers at the slot. In other words, the through slot is a complete opening in the said at least one of the first and second layers at the location at which the slot is formed.

Furthermore, a penetration material may at least partially and particularly entirely occupy through slots and/or blind slots on the external surface of the photovoltaic module, the penetration material being composed particularly of the material from which the encapsulating assembly is made.

The slots may be set out in a matrix configuration, in other words the slots are approximately in rows and in columns. Slots may also be set out in a concentric configuration, in other words such that at least part of the slots define shapes of a circle or arcs of circles, either alone or in combination.

The photovoltaic module according to the invention can also comprise a gas barrier layer covering said at least one of the first and second layers, particularly composed of a protection film, called the gas barrier film.

Moreover, the first layer forming the front face, and/or the second layer forming the back face of the photovoltaic module may be single layer or multiple layer. In particular, the first layer forming the front face and/or the second layer forming the back face may comprise a set of transparent or non-transparent layers superposed on each other.

When the first layer forming the front face of the photovoltaic module is transparent, the second layer forming the back face of the photovoltaic module may or may not be transparent, and in particular may be opaque.

The space between two adjacent photovoltaic modules, or consecutive or adjacent modules, can be greater than or equal to 1 mm, particularly between 1 and 30 mm, and preferably greater than or equal to 3 mm, and especially between 10 and 20 mm.

Moreover, the purpose of another aspect of the invention is a method of making a photovoltaic module as defined above, characterised in that it comprises the following steps in sequence:

a) make slots in the polymer material of said at least one of the first and second layers of the photovoltaic module,

b) lamination of the set of layers forming the photovoltaic module.

Step a) to make the slots may be done using a casting mould or by machining.

According to a first variant, step a) to make the slots may include the formation of a least a plurality of through slots and/or blind slots on the external surface of the photovoltaic module, and the method according to the invention may include the intermediate step a′), after step a) in which slots are made and before the lamination step b), consisting of placing said at least one of the first and second layers in which slots are formed directly in contact with the encapsulating assembly such that, during the lamination step b), the material of the encapsulating assembly melts and at least partially penetrates into the slots, the material of the encapsulating assembly then at least partly forming said jointing material.

According to a second variant, step a) to make the slots may include the formation of a least a plurality of through slots and/or blind slots on the external surface of the photovoltaic module, and the method according to the invention may include the intermediate step a″), after step a) in which slots are made and before the lamination step b), consisting of placing at least one penetration material between the encapsulating assembly and said at least one of the first and second layers in which slots are formed such that, during the lamination step b), the penetration material melts and at least partially penetrates into the slots, the penetration material then at least partly forming said jointing material.

According to a third variant, step a) to make the slots may include the formation of a least a plurality of through slots and/or blind slots on the external surface of the photovoltaic module, and the method according to the invention may include the intermediate step a′″), after step a) in which slots are made and before the lamination step b), consisting of placing at least one penetration material in said slots and then placing said at least one of the first and second layers in which slots are formed comprising said at least one penetration material directly in contact with the encapsulating assembly such that, during the lamination step b), the penetration material already in place inside the slots then at least partly forms said jointing material.

This penetration material can for example be placed inside slots by overmoulding of the material on the layer containing the slots, for example being composed of a heat-set material, particularly a rubber material. The “heat-set” nature of the protection material thus makes it possible for it to not melt and not move during the lamination step b).

Furthermore, the method according to the invention may also include step c), after the lamination step b), to position a gas barrier layer covering said at least one of the first and second layers, particularly composed of a protection film, called the gas barrier film.

The photovoltaic module and the manufacturing method according to the invention may comprise any one of the previously described characteristics, taken in isolation or in any technically possible combination with other characteristics.

### BRIEF DESCRIPTION OF THE DRAWINGS

The invention will be better understood after reading the following detailed description of non-limitative example embodiments of the invention, and an examination of the diagrammatic and partial figures in the appended drawing on which:

FIG. 1 shows a sectional view of a conventional example of a photovoltaic module containing crystalline photovoltaic cells,

FIG. 2 shows an exploded view of the photovoltaic module in FIG. 1.

FIGS. 3, 4 and 5 show a perspective view, a top view and a sectional view respectively of a first example embodiment of a front face of a photovoltaic module conforming with the invention,

FIGS. 6 and 7 show a perspective view and an enlarged perspective view respectively of a second example embodiment of a front face of a photovoltaic module conforming with the invention,

FIG. 8 shows a top view of a third example embodiment of a front face of a photovoltaic module conforming with the invention,

FIG. 9 shows a top view of a fourth example embodiment of a front face of a photovoltaic module conforming with the invention,

FIG. 10 shows a sectional view of an example photovoltaic module conforming with the invention comprising a gas barrier layer,

FIG. 11 shows a sectional view of another example of a photovoltaic module according to the invention comprising through slots into which part of the material of the encapsulating assembly has penetrated,

FIG. 12 shows a sectional view of yet another example of a photovoltaic module according to the invention comprising blind slots on the external surface of the photovoltaic module into which part of the material of the encapsulating assembly has penetrated, and

FIG. 13 shows a sectional view of yet another example of a photovoltaic module according to the invention comprising through slots into which part of a penetration material previously added to the encapsulating assembly has penetrated,

In all these figures, identical references can designate identical or similar elements.

Furthermore, the different parts shown on the figures are not necessarily all at the same scale, to make the figures more easily understandable.

### DETAILED PRESENTATION OF PARTICULAR EMBODIMENTS

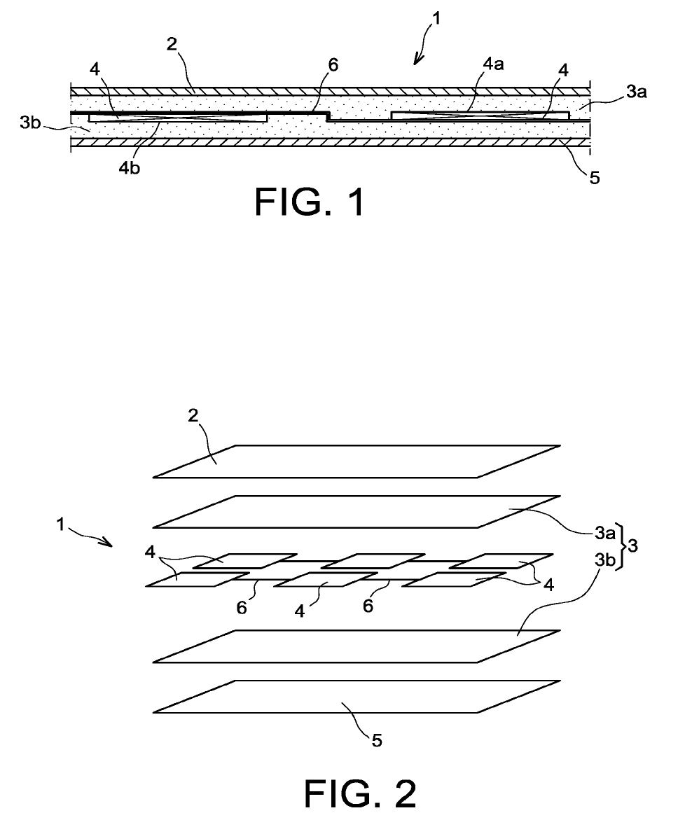

FIGS. 1 and 2 have already been described in the part dealing with the state of prior art.

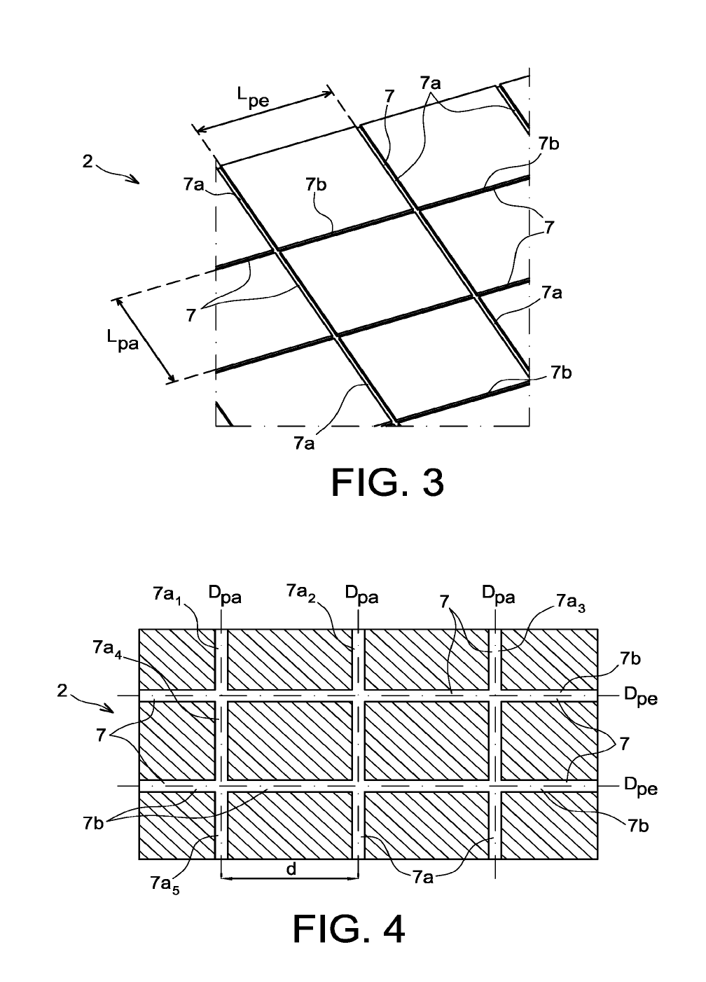

In all the examples conforming with the invention described below with reference to FIGS. 3 to 13, it is assumed that the external face of the photovoltaic module 1, composed of a polymer material in which slots 7 are formed making up expansion joints, corresponds to the first layer 2 of the photovoltaic module 1, in other words to the front face 2 of the photovoltaic module 1.

Obviously, this choice is in no way limitative. Thus, as a variant, the second layer 5, namely the back face 5 of the photovoltaic module 1 could correspond to the external face made of a polymer material in which slots 7 are formed. As another variant, each of the first layer 2 and the second layer 5, namely the front face 2 and the back face 5 of the photovoltaic module 1 could be made from a polymer material and could be provided with slots 7 forming expansion joints.

Furthermore, only the front face 2 of the photovoltaic module 1 is shown on FIGS. 3 to 9. Thus, refer to FIGS. 1 and 2 described previously for other elements forming part of the photovoltaic module 1.

Furthermore, the front face 2 and the back face 5 of the photovoltaic module 1 are preferably made from a polymer material made from either poly methyl methacrylate (PMMA) or polycarbonate (PC). If PMMA is used, this is a polymer material composed of polymer chains base on methyl methacrylate as the majority monomer during polymerisation. This material may be single phase or multi-phase, with reference to the number of polymer phases forming it. This definition thus comprises non-exclusively, single-phase PMMA or classical PMMA, also called unmodified acrylic impact glass, as marketed by the Altuglas Company® in different forms, colours, textures and sets of optical and physicochemical properties (including thermomechanical properties). The definition also includes multi-phase PMMA (at least two distinct polymer phases) or impact PMMA, such as classical impact PMMA and nanostructured impact PMMA like that marketed by the Altuglas Company® under the Altuglas® Shield-Up® brand.

Refer firstly to FIGS. 3 to 5 that show a perspective view, a top view and a sectional view respectively of a first example embodiment of a photovoltaic module 1 conforming with the invention,

According to the invention, the single-piece front face 2 of the photovoltaic module 1 is composed of a polymer material in which slots 7 are formed making up expansion joints.

Although not shown on FIGS. 3 to 5, each slot 7 is at least partly occupied by a so-called “soft” joint material with a Young's modulus E at ambient temperature lower than the Young's modulus E of the polymer material of the front face 2 at ambient temperature, and particularly a Young's modulus at ambient temperature of less than or equal to 50 MPa, or even 30 MPa or even better 10 MPa, whereas the polymer material of the front face 2 has a Young's modulus E at ambient temperature equal to between 400 MPa and 10 GPa.

The presence of such a soft material enables the front face 2 of the module 1 to compensate for the disadvantages resulting from thermal expansion.

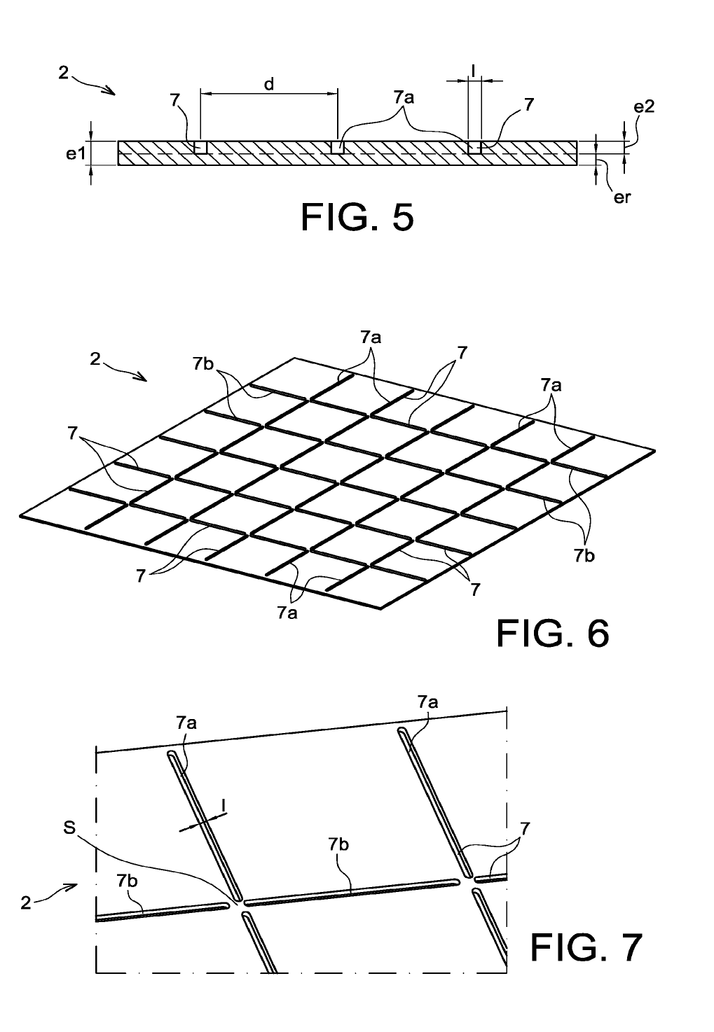

Furthermore, as can be seen on FIG. 5, the thickness e2 of the slots 7 is less than or equal to the thickness e1 of the polymer material of the front face 2, for example between 0.5 and 10 mm.

The coefficient of thermal expansion (CTE) of the polymer material on the front face is between 30 and 200 ppm/° C. at a temperature close to ambient temperature, which is a high coefficient of thermal expansion (CTE) and the coefficient of thermal expansion (CTE) of the jointing material occupying the slots 7 is between 30 and 500 ppm/° C. at a temperature close to ambient temperature.

Advantageously, the joint material that occupies the slots 7 can be chosen from among a polymer material, particularly identical to the polymer material from which the encapsulating assembly 3 is made, or a penetration material 8 as will be explained later, or a gas and particularly air. It is important to note that according to one embodiment of the invention, the slots 7 may be occupied solely by ambient air. For the purposes of the invention, the expression “jointing material” or “soft material” also covers ambient air.

Advantageously, the jointing material has a good elastic return, and is flexible and lightweight in comparison with the polymer material of the front face 2, to assure that it can perform its role as an expansion joint in the case of high thermal stresses.

Moreover, in the example embodiment in FIGS. 3 to 5, the slots 7 are elongated, and are straight. They are set out in a matrix configuration, in other words according to a continuous assembly of rows and columns, as can be seen on FIGS. 3 and 4.

Furthermore, the slots 7 in the example embodiment in FIGS. 3 to 5 are blind, and in particular are blind on the encapsulating part 3 but do open up of the external surface of the photovoltaic module 1. In other words, the contour along the length of the slots 7 is delimited underneath by the encapsulating assembly 3.

Consequently, there is a residual thickness eᵣ of material on the front face 2 at the blind slots 7, that is less than or equal to 20% of the thickness e1 of the polymer material of the front face 2, and particularly less than or equal to 0.1 mm.

Furthermore, the slots 7 according to the invention advantageously comprise firstly a set of first slots 7a said to be “parallel”, in other words first slots 7a for which their largest dimension Lpa extends along first directions Dpa approximately parallel to each other or coincident with each other, and secondly a set of second “perpendicular” slots 7b, in other words second slots 7b for which their largest dimension Lpe extends along second directions Dpe approximately perpendicular to the first directions Dpa along which the largest dimension Lpa of the first slots 7a extends.

In particular, as can be seen on FIGS. 3 and 4, the first parallel slots 7a are arranged so as to form parallel columns along direction Dpa, and second perpendicular slots 7b are arranged so as to form parallel lines along direction Dpe. All directions Dpe are perpendicular to directions Dpa.

Furthermore, as be seen on FIGS. 4 and 5, the distance d between two so-called “adjacent” first parallel slots 7a, in other words two first parallel slots 7a for which their largest dimension Lpa extends along first directions Dpa that are practically coincident with each other and for which there are no other first slots 7a between them, or two first parallel slots 7a for which their largest dimension Lpa extends along approximately parallel first directions Dpa and for which there is no other first direction Dpa along which a first parallel slot 7a extends, is less than or equal to 200 mm and is greater than or equal to 40 mm.

It can be noted on FIG. 4 that firstly the first parallel slots 7a₁ and 7a₂, and secondly the first parallel slots 7a₂ and 7a₃ form first adjacent parallel slots. The first parallel slots 7a₁ and 7a₂ together with the second parallel slots 7a₂ and 7a₃ constitute two first parallel slots having their longest direction Lpa along first directions Dpa approximately parallel to each other and they are not separated from each other by any other first direction Dpa.

On the other hand, the first parallel slots 7a₁ and 7a₃ are not adjacent because the first parallel slot 7a₂ is located between them.

Furthermore, the first parallel slots 7a₁ and 7a₄ are adjacent slots because they constitute two first parallel slots having their longest dimension Lpa along first directions Dpa approximately coincident with each other and they are not separated by any other first slot.

However, the first parallel slots 7a₁ and 7a₅ are not adjacent because the first parallel slot 7a₄ is between them.

Refer to FIGS. 6 and 7 that show a perspective view and an enlarged perspective view respectively of a second example embodiment of the front face 2 of a photovoltaic module 1 conforming with the invention,

Only the elements that are different from the first embodiment in FIGS. 3 to 5 are described below.

Thus, in this second example, the slots 7 are elongated and oblong in shape. They are through slots (fully open) and are set out in a matrix configuration, namely in the form of rows and columns, as shown in the first example in FIGS. 3 to 5.

The same comments as above about the size of the slots 7 are applicable here

Furthermore, as can be seen on FIG. 7, the section s of material remaining between a first parallel slot 7a and a second perpendicular slot 7b is greater than or equal to 2 mm².

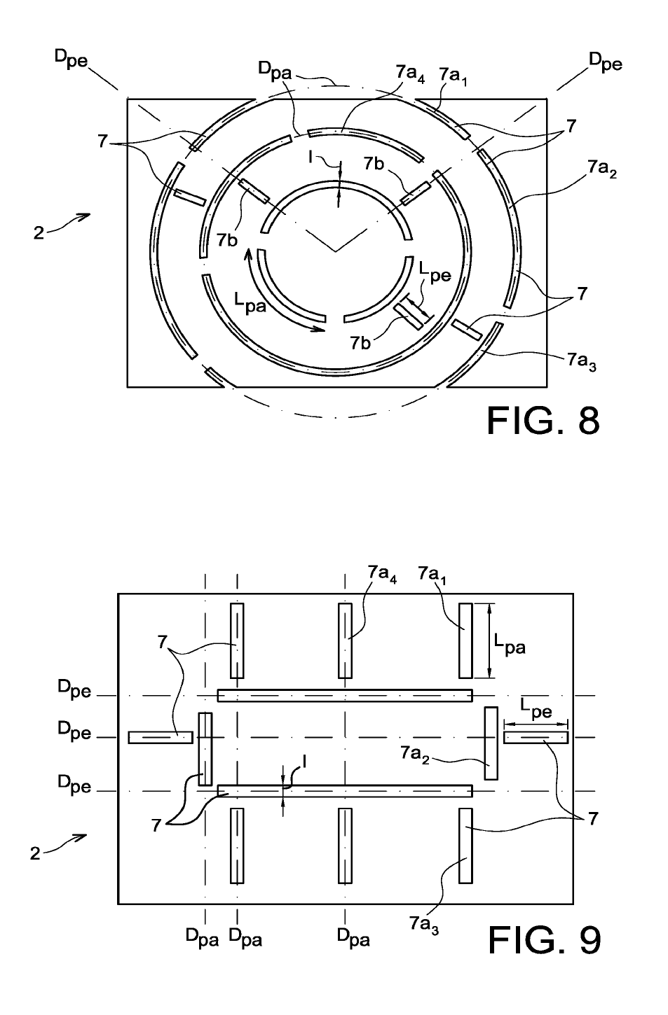

Furthermore, with reference to FIG. 8, the figure shows a top view of a third example embodiment of the front face 2 of a photovoltaic module according to the invention,

Unlike the first and second embodiments of the invention described above, the slots 7 in the example in FIG. 8 are arranged in a concentric configuration, in other words they are arranged approximately in circles or portions of circles.

The slots 7 are elongated but in this case the first parallel slots 7a are in the form of arcs of a circle and the second perpendicular slots 7b are straight.

Note that in this third example in FIG. 8, the first directions Dpa are curves that are parallel to each other or coincident with each other. The second directions Dpe are straight lines perpendicular to the first directions Dpa.

Furthermore, the largest dimensions Lpa of the first parallel slots 7a correspond to lengths of the corresponding arcs of a circle, while the largest dimensions Lpe of the second perpendicular slots Lpe of the second perpendicular slots 7b correspond to the lengths of the corresponding straight segments.

Furthermore and as examples, the first parallel slots 7a₁ and 7a₄ are adjacent, and the first slots 7a₁ and 7a₂ are also adjacent. On the other hand, the first slots 7a₁ and 7a₃ are not adjacent.

The same comments as above about the size of the slots 7 are applicable here

With reference to FIG. 9, the figure shows a fourth example embodiment of the front face 2 of a photovoltaic module according to the invention,

In this example, the slots 7 are arranged in a concentric matrix configuration. Firstly the first parallel slots 7a are arranged in columns and the second perpendicular slots 7b are arranged in rows. Secondly, the arrangement of the slots 7 appears to define concentric circles.

It can also be noted that the first parallel slots 7a₁ and 7a₂ are adjacent, and the first parallel slots 7a₁ and 7a₄ are also adjacent. On the other hand, the first parallel slots 7a₁ and 7a₃ are not adjacent.

Furthermore, in all the examples described, the width I of the slots 7, for example shown in FIG. 5 or FIGS. 7 to 9, is greater than or equal to 2 mm, and less than or equal to 3 mm.

Moreover, in the third and fourth examples shown in FIGS. 8 and 9 respectively, the slots may be through or blind, and may be either on the external surface of the photovoltaic module 1, or on the encapsulating assembly 3.

Furthermore, when the slots 7 are through or blind on the external surface of the photovoltaic module 1, they may be at least partially occupied by a penetration material 8 or by the encapsulating assembly 3 as described below, that then acts as jointing material.

It should also be noted that in the examples described above with reference to FIGS. 3 to 7 and 9, the distinction between first parallel slots 7a and second perpendicular slots 7b is arbitrary, considering the positioning configurations shown. In other words, the elements designated on these figures as being the first parallel slots 7a and the elements designated on these figures as the second perpendicular slots 7b could be inverted such that the characteristics described above for the first parallel slots 7a, and particularly related to the distance d, are applicable for the second perpendicular slots 7b, and vice versa.

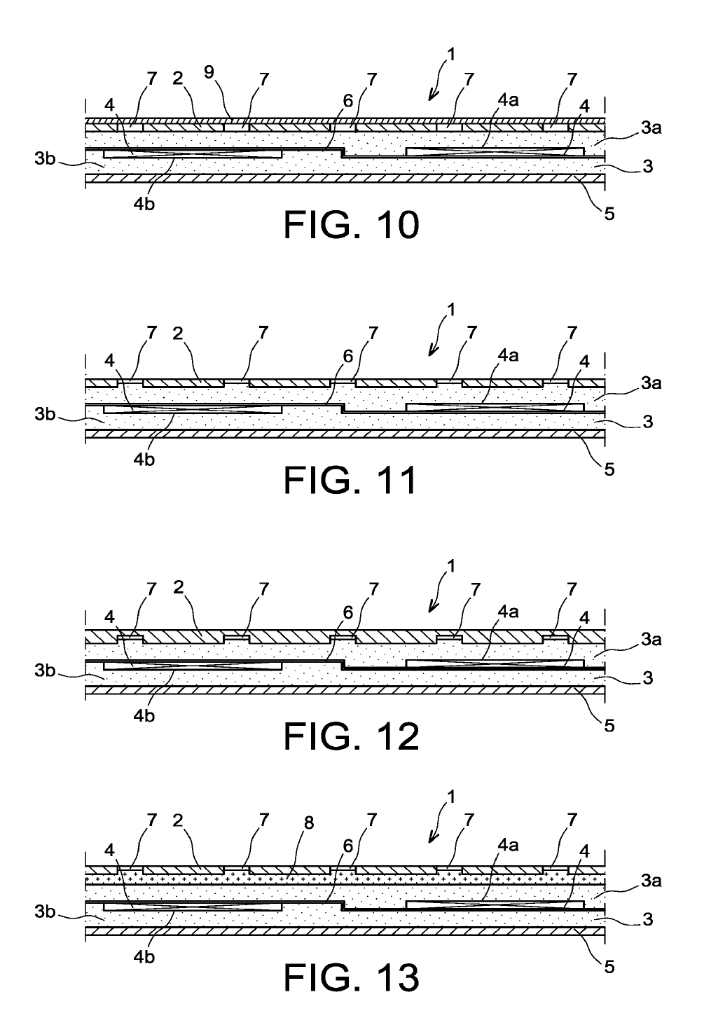

We will now refer to FIGS. 10 to 13 to describe different examples of photovoltaic modules 1 according to the invention, obtained according to various embodiments of the manufacturing method according to the invention.

Firstly, FIG. 10 shows a sectional view of an example photovoltaic module conforming with the invention comprising a gas barrier layer 9.

In this example, the photovoltaic module 1 comprises a front face 2 on which there are through slots 7, and the gas barrier layer 9, for example composed of a protection film 9 called the protection film 8 called the gas barrier film, covers the front face 2 and the through slots 7.

In this way, the gas barrier layer 9 can for example limit the penetration of water vapour and oxygen through the through slots 7.

Furthermore, FIG. 11 shows a sectional view of another example of a photovoltaic module 1 according to the invention comprising through slots 7 into which part of the material of the encapsulating assembly 3 has penetrated.

During the lamination step of all layers forming the photovoltaic module 1, the material used for the encapsulating assembly 3 can melt and thus at least partly occupy the through slots 7, then forming the jointing material.

FIG. 12 also shows a sectional view of yet another example of a photovoltaic module 1 according to the invention comprising blind slots 7 on the external surface of the photovoltaic module 1 into which part of the material of the encapsulating assembly 3 has penetrated.

As for the previous example, the increase in temperature during the lamination step causes penetration of the material of the encapsulating assembly 3 into the slots 7 that then form the jointing material.

Finally, FIG. 13 shows a sectional view of another example of a photovoltaic module 1 according to the invention comprising through slots 7 into which part of a penetration material 8 previously added to the encapsulating assembly 3 has penetrated,

In other words, a layer of penetration material 8 is added to the encapsulating assembly 3 before application of the front face 2, and then the lamination step includes heating of the penetration material 8 that can flow into the slots 7, the penetration material 8 then forming the jointing material.

In all cases, the presence of slots 7 on the front face 2 of the photovoltaic module 1 and the presence of the jointing material in these slots 7 can limit the stressing effects of thermal expansion described above.

Obviously, the invention is not limited to the example embodiments that have just been described. An expert in the subject can make various modifications to it.

The expression “comprising one” must be understood as being synonymous with “comprising at least one”, unless mentioned otherwise.

1. A Photovoltaic module, comprising:
a first transparent layer forming a front face of the photovoltaic module that receives a light flux,
a plurality of photovoltaic cells arranged side by side and electrically connected together,
an assembly encapsulating the plurality of photovoltaic cells,
a second layer forming a back face of the photovoltaic module,
the encapsulating assembly and the plurality of photovoltaic cells being located between the first and the second layers,
wherein at least the first or the second layers is composed of at least one polymer material, in which slots are formed making up expansion joints, said at least first or second layer provided with slots being one integral piece,
wherein the slots are at least partially occupied by a soft jointing material with a Young's modulus at ambient temperature being less than the Young's modulus at ambient temperature of the polymer material of said at least one of the first and second layer and with a thickness less than or equal to the thickness of the polymer material of said at least one of the first or second layers, and
wherein the slots are at least partly open.

2. The module according to claim 1, wherein the jointing material has a Young's modulus at ambient temperature of 20 times less than the Young's modulus at ambient temperature of the polymer material of said at least one of the first and second layers.

3. The module according to claim 1, wherein the jointing material has a Young's modulus at ambient temperature of less than or equal to 50 MPa, whereas the polymer material of said at least one of the first and second layers has a Young's modulus E at ambient temperature equal to between 400 MPa and 10 GPa.

4. The module according to claim 1, wherein the thickness of the polymer material of said at least one of the first and second layers is between 0.5 and 10 mm.

5. The module according to claim 1, wherein a coefficient of thermal expansion of the polymer material of said at least one of the first and second layers is between 30 and 200 ppm/° C. at temperatures close to ambient temperature, and wherein a coefficient of thermal expansion of the jointing material occupying the slots is between 30 and 200 ppm/° C. at a temperature close to ambient temperature.

6. The module according to claim 1, wherein said at least one polymer material of said at least one of the first and second layers is optionally chosen from among poly methyl methacrylate (PMMA) or polycarbonate (PC).

7. The module according to claim 1, wherein the jointing material occupying the slots is chosen from among a polymer material or a gas.

8. The module according to claim 1, wherein each of the first and second layers is composed of the at least one polymer material, in which the slots are formed making up the expansion joints, each of the first and second layers provided with slots being one integral piece, and the slots being at least partially occupied by the soft jointing material with a Young's modulus at ambient temperature less than the Young's modulus of each of the first and second layers and with the thickness less than or equal to the thickness of each of said first and second layers.

9. The module according to claim 1, wherein the slots are elongated, straight and/or in the form of an arc of a circle.

10. The module according to claim 1, wherein the slots comprise a set of first slots whose largest dimension extends along first directions approximately parallel to each other or coincident with each other, and a set of second slots whose largest dimension extends along second directions approximately perpendicular to the first directions along which the largest dimension of the first slots extends.

11. The module according to claim 10, wherein a distance between two first parallel slots whose largest dimension extends along the first directions that are practically coincident with each other and which have no other first slots in between, or between two first parallel slots whose largest dimension extends along approximately parallel to the first directions and which have no other first direction along which a first parallel slot extends, is less than or equal to 200 mm.

12. The module according to claim 10 wherein a distance between two first parallel slots whose largest dimension extends along the first directions that are practically coincident with each other and which has no other first slots in between, or between two first parallel slots whose largest dimension extends along approximately parallel to the first directions and which has no other first direction along which a first parallel slot extends, is greater than or equal to 40 mm.

13. The module according to claim 10, wherein a section of material remaining between a first parallel slot and a second perpendicular slot is greater than or equal to 2 mm².

14. The module according to claim 1, wherein a width of the slots is greater than or equal to 2 mm.

15. The module according to claim 1, wherein a width of the slots is less than or equal to 3 mm.

16. The module according to claim 1, wherein the slots are at least partly open.

17. The module according to claim 16, wherein a residual thickness of material from said at least one of the first and second layers at blind slots is less than or equal to 20% of the thickness of the polymer material in said at least one of the first and second layers.

18. The module according to claim 1, wherein the slots are entirely open.

19. The module according to claim 17, wherein a penetration material at least partially occupies through the slots and/or blind slots over the external surface of the module, the penetration material being composed of material from which the encapsulating assembly is made.

20. The module according to claim 1, wherein the slots are set out in a matrix configuration.

21. The module according to claim 1, wherein the slots are set out in a concentric configuration such that at least part of the slots define shapes of a circle or arcs of circles, either alone or in combination.

22. The module according to claim 1, further comprising a gas barrier layer covering said at least one of the first and second layers.

23. A method for making the module according to claim 1, the method comprising:
a) making the slots in the polymer material of said at least one of the first and second layers, and
b) subsequently laminating the first layer, the plurality of the photovoltaic cells, the assembly, and the second layer, thereby forming the module.

24. The method according to claim 23, wherein a) is performed by using a casting mould or by machining.

25. The method according to claim 23,
wherein a) comprises: forming a least a plurality of through slots and/or blind slots on the external surface of the module, and
wherein the method further comprises, after a) and before b), placing said at least one of the first and second layers in which the slots are formed directly in contact with the encapsulating assembly such that, during b), the material of the encapsulating assembly melts and at least partially penetrates into the slots, the material of the encapsulating assembly then at least partly forming said jointing material.

26. The method according to claim 23,
wherein a) comprises: forming a least a plurality of through slots and/or blind slots on the external surface of the module, and
wherein the method further comprises, after a) and before b), placing at least one penetration material between the encapsulating assembly and said at least one of the first and second layers in which the slots are formed such that, during b), the penetration material melts and at least partially penetrates into the slots, the penetration material then at least partly forming said jointing material.

27. The method according to claim 23, wherein a) comprises: forming a least a plurality of through slots and/or blind slots on the external surface of the module, and
wherein the method further comprises, after a) and before b), placing at least one penetration material in said slots and then placing said at least one of the first and second layers in which the slots are formed comprising said at least one penetration material directly in contact with the encapsulating assembly such that, during b), the penetration material already in place inside the slots then at least partly forms said jointing material.

28. The method according to claim 23, further comprising:
c) after b), putting a gas barrier layer into place covering said at least one of the first and second layers.
